(19) United States
(12) Patent Application Publication
(10) Pub. No.: US 2005/0225949 A1
(43) Pub. Date: Oct. 13, 2005

(54) Circuit arrangement for controlling electromotive driving means of a mobile working machine, particularly of an industrial truck

(76) Inventors: Otto Kollmannsberger, Moosburg (DE); Michael Ries, Aschaffenburg (DE)

Correspondence Address: EDWARDS & ANGELL, LLP, P.O. BOX 55874, BOSTON, MA, 02205, US

(21) Appl. No.: 10/516,190

(22) PCT Filed: May 28, 2003
(86) PCT No.: PCT/EP03/05664

§ 371 Date: May 2, 2005

(30) Foreign Application Priority Data
May 31, 2002 (DE) 102241686
Jul. 2, 2002 (DE) 202102173

(51) Int. Cl. H05K 7/00

(52) U.S. Cl. 361/728

(57) ABSTRACT

The invention relates to a circuit arrangement for controlling electric motors of an industrial truck, comprising an electronic control stage with a main board (16) and an exchangeable board (22), and comprising a power-output stage (14). The exchangeable board (22) can be detached with little effort from the main board (16) that is fixed inside a case (12). The exchangeable board (22) comprises a group of selected control stage components (24) for which, statistically, a greater need for exchanging and/or a greater need for testing and/or a greater need for variants to be kept ready on the side of the producer exists than for the components (18) of the main board (16).

The invention relates to a circuit arrangement for controlling electromotive driving means of a mobile working machine, particularly of an industrial truck, the circuit arrangement comprising an electronic control stage and a power output stage.

Industrial trucks, by way of example electric forklift trucks, are known which comprise at least one electric motor, for example three-phase electric motor as traction driving motor, a further electric motor as steering motor, that is to say as driving means for the steering movements of one steerable wheel or, if appropriate, of a plurality of steerable wheels, and a further electric motor as pump motor. The pump motor drives a hydraulic pump of the hydraulic lifting device of the industrial truck.

The electric motors, particularly the traction driving motor and the pump motor, are very powerful driving means and dimensioned for a large operating current requirement. The operating current is supplied by the stacker's onboard battery, which, depending on the embodiment, may have a rated voltage of 24 V, 48 V or 80 V, by way of example. The current requirement of the traction driving motor and of the pump motor may be hundreds of amperes depending on the operating conditions. The electric motors are supplied with current from the onboard battery via a power output stage in a controlled manner.

It is advantageous that at least most of the electronic or electrical components of the power output stage, such as the power transistors, for instance, are provided on a common circuit board or card.

An electronic control stage serves for controlling the power output stage in a manner dependent on desired value and actual value signals. Desired value signals are provided by electronic transmitters, by way of example, which respond to the actuation of assigned operating elements. A desired value signal for the control of the traction driving motor is supplied by an accelerator pedal actuation sensor and is a measure of the desired speed of the industrial truck. A further desired value signal is the travel direction signal supplied by a travel direction transmitter according to the actuation of a travel direction switch.

A desired value signal for controlling the steering motor may be provided by a steering angle transmitter, by way of example, which provides a signal according to the actuation of the steering wheel of the industrial truck.

Desired value signals for controlling the pump motor are supplied by transmitter elements that are connected to operating elements for setting the lifting and lowering operation, etc. of the hydraulic lifting device.

The electronic control stage receives actual value signals from the diverse actual value transmitters that are provided e.g. for measuring the present traveling speed, the instantaneous steering angle of the steerable wheels, the respective lifting state of the hydraulic lifting device etc.

The electronic control stage usually comprises a multiplicity of electronic components. These include integrated circuits such as, for instance, microprocessors, memory modules, input/output modules, and furthermore sensor circuits and also driver circuits for the power transistors of the power output stage. The electronic control stage of known circuit arrangements of the type under consideration here furthermore comprises plug connection elements for connecting signal lines and data bus lines, one or more temperature sensors, safety switching elements such as an emergency stop relay, and indication elements, such as, for instance, light emitting diodes or LCD display elements.

In the known examples, the components of the electronic control stage are provided on a common control stage circuit board. The layout of said control stage circuit board and thus the arrangement of the associated electronic components have essentially been chosen from the standpoint of optimizing space. Accommodating the control stage components on at least one control stage circuit board that is separate from the power output stage circuit board is expedient in order that the normally temperature-sensitive control stage components can be thermally insulated from the power output stage as well as possible and using simple means.

If the relatively sensitive control stage exhibits a defect, then this can be remedied by exchanging it for an entirely satisfactory control stage circuit board. However, on account of the multiplicity of high-quality electronic components on the control stage circuit board, such exchange is associated with considerable costs.

Repairing a defective control stage circuit board is usually uneconomic since the defect analysis and the exchange of components of the highly densely populated circuit board are costly and complicated measures.

Moreover, for the manufacturer of the circuit arrangements under consideration here or of the working machines equipped therewith, the problem may arise that, when selling its product in different countries, said manufacturer has to take account of differing plug connector standards for data transmission interfaces of the control stage and thus corresponding variants of its circuit arrangement.

The invention is based on the object of overcoming the abovementioned disadvantages of the known circuit arrangements and providing a circuit arrangement of the type mentioned in the introduction which in most cases enables a faster, simpler and more cost-effective elimination of disturbances or failures of the electronic control stage and/or which can be offered by the manufacturer more cost-effectively than hitherto in different variants.

In order to achieve this object, a circuit arrangement of the type mentioned in the introduction is proposed having an electronic control stage and a power output stage, in which the electronic control stage has at least one main circuit board that is arranged in a housing of the circuit arrangement and is populated with electronic components and at least one exchangeable circuit board that is electrically connected to the main circuit board but can be separated from the main circuit board as required with little effort, the exchangeable circuit board having a group of selected control stage components for which, statistically, a greater need for exchanging and/or a greater need for checking and/or a greater need for variants to be kept ready on the part of the manufacturer exists than for the components of the main circuit board.

The invention is thus based on the concept of assembling on the exchangeable circuit board components of the control stage that have proved to be particularly susceptible to wear and thus in need of exchange and/or components of the control stage that have to be checked relatively frequently and should therefore be easily accessible, and/or components of the control stage that are intended to differ for different types of working machines.

Insofar as the components of the control stage that are more susceptible to wear are provided on the exchangeable circuit board, a defect in the control stage can be eliminated with a high degree of probability by exchanging the exchangeable circuit board. The number of components on the exchangeable circuit board should be kept as low as possible in order that the costs of the exchangeable circuit board remain low. Thus, the number of components on the exchangeable circuit board should as far as possible be lower than 25% of the overall number of electronic components of the control stage.

For reasons of being able to handle the exchangeable circuit board more simply, the board size thereof should be as small as possible and reach no more than one third of the board size of the main circuit board.

Preferably, the power output stage circuit board, the main circuit board of the control stage and the exchangeable circuit board of the control stage are accommodated in a common housing. In a particularly preferred embodiment, the exchangeable circuit board is dimensioned such that, through an access opening provided in a side part of the housing, it can be separated from the main circuit board and be removed from the housing or be introduced into the housing and be electrically connected to the main circuit board, the exchangeable circuit board preferably being arranged on a cover screen for closing the access opening.

Particularly if the electrical connection between main circuit board and exchangeable circuit board is realized by a readily releasable plug connection in accordance with one embodiment of the invention, the exchangeable circuit board can be exchanged in a particularly simple and rapid manner.

Since the exchangeable circuit board can be conveniently demounted, it is also possible for the components situated thereon to be checked in a simple manner outside the housing.

It also lies within the scope of the invention to assemble on the exchangeable circuit board components of the control stage for which a greater need for variants to be kept ready on the part of the manufacturer exists than for the remaining components of the control stage. Such a greater need for variants of components to be kept ready on the part of the manufacturer may arise, by way of example, due to the fact that differing plug connector standards or interface technologies or, if appropriate, differing requirements with regard to the indication elements, etc. exist in different countries. By concentrating these components that vary from case to case on the exchangeable circuit board, it is possible for the manufacturer to design the circuit arrangement for the rest in series and in identical type and merely to adapt the exchangeable circuit board in accordance with the respective requirements.

The invention also relates to a mobile working machine, in particular an industrial truck, having at least one electric motor, in particular at least one electric traction motor and/or an electric motor as driving source for a lifting device and/or an electric steering motor, and having a circuit arrangement according to the invention for controlling the at least one electric motor.

The invention is explained in more detail below with reference to the figures.

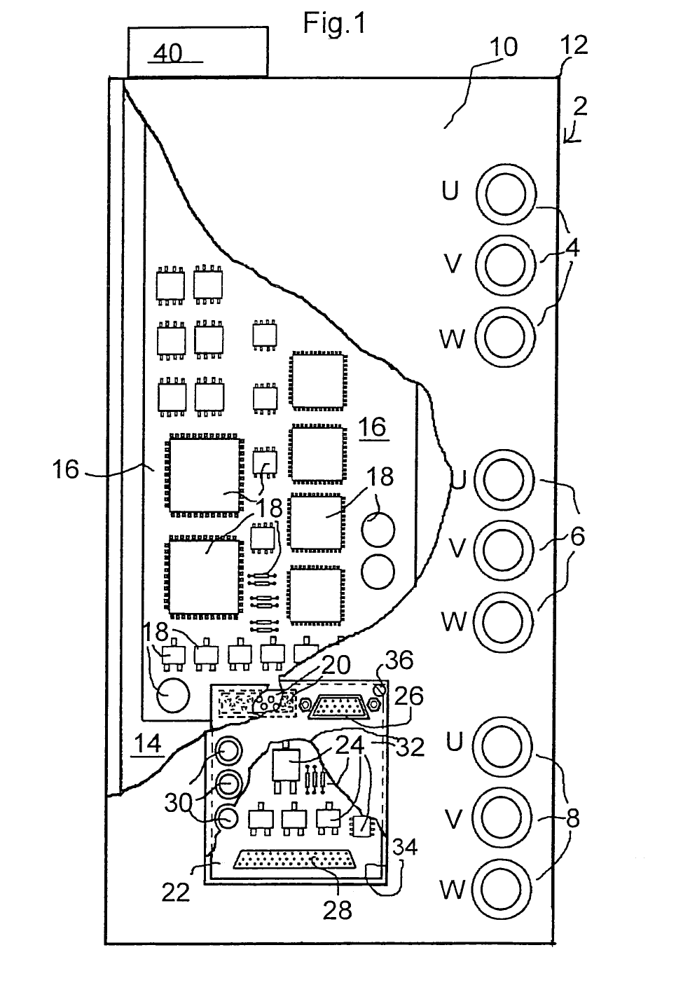

FIG. 1 shows a plan view of a circuit arrangement according to the invention in a schematic illustration, said plan view being depicted in multiply cut-away fashion.

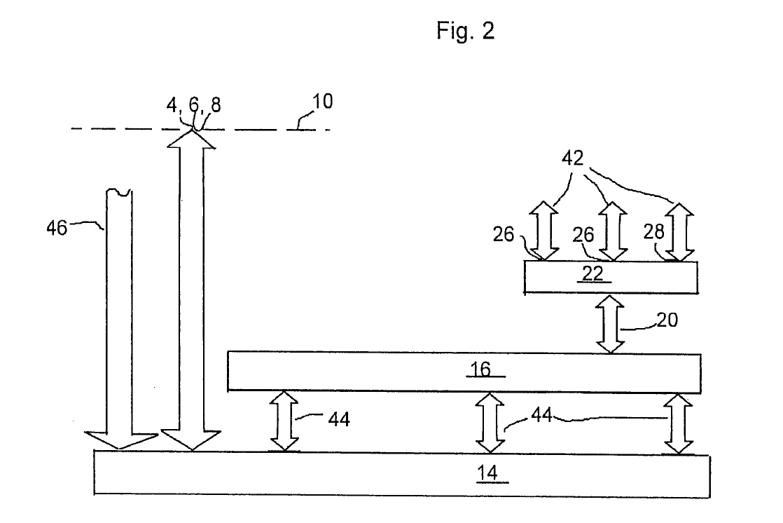

FIG. 2 shows a schematic block illustration of a circuit arrangement according to the invention.

The subject matter shown in FIG. 1 involves a control unit for an electric forklift truck having a three-phase motor as traction driving motor, a further electric motor as steering motor and an additional electric motor as pump motor for the hydraulic pump of the hydraulic lifting device. The control unit 2 has power supply terminals 4 for the traction driving motor, power supply terminals 6 for the pump motor and power supply terminals 8 for the steering motor. Power cables of the relevant motors are to be connected to said power supply terminals 4, 6, 8. The power supply terminals 4, 6, 8 are situated on a side part 10 of the unit housing 12. In the unit housing 12, the power supply terminals 4, 6, 8 are connected to a power output stage formed from a circuit board 14 situated right at the bottom in the housing 12 in FIG. 1. The power output stage circuit board 14 is populated with output stage components (not shown). These include power transistors for controlling the current flow from the battery of the electric forklift truck to the traction driving motor, the steering motor and the pump motor, respectively. Said power transistors may be MOSFET transistors, by way of example. The power output stage circuit board 14 may furthermore be populated with EMC filter components, cooling elements, temperature measuring components etc.

The terminals for connecting the control unit 2 to the onboard battery are not discernible in FIG. 1.

The main circuit board 16 of the electronic control stage is situated above the power output stage circuit board 14 fixed in the housing 12, the main circuit board 16 being screwed to the power output stage circuit board 14 at a distance by means of post strips (not shown). The main circuit board 16 of the control stage provided for controlling the power output stage has a multiplicity of electronic components 18 in a relevant circuitry. Said electronic components include microcontrollers or microcomputer elements such as, for instance, microprocessors, memory modules, I/O modules or interface and driver modules. The main circuit board 16 is furthermore populated with sensor elements for sensing current, voltage and rotational speed of electric motors, etc. and, moreover, has voltage supply elements and MOSFET driver circuits for the power output stage.

The main circuit board 16 is electrically connected to an exchangeable circuit board 22 via a plug connection 20. The exchangeable circuit board 22 is likewise associated with the control stage for the power output stage 14. The exchangeable circuit board 22 is populated inter alia with a selection of components 24 that have a greater statistical probability of failure and thus a lower statistical life expectancy than the components 18 of the main circuit board 16. However, the exemplary embodiment shown is not intended to rule out the situation in which insensitive or long-lived components are also accommodated on the exchangeable circuit board 22. As can be seen in FIG. 1, the number of components on the exchangeable circuit board 22 should, however, be as small as possible in comparison with the number of components on the main circuit board 16.

In a preferred embodiment, the exchangeable circuit board 22 comprises circuit elements of a charging circuit for charging the buffer capacitors of the power output stage. Said circuit elements also include, inter alia, a decoupling diode and a temperature-dependent resistor, for example a PTC thermistor.

The exchangeable circuit board 22 furthermore has elements of a safety circuit, namely at least one emergency stop relay and also sensor elements for a main contactor (not shown).

The exchangeable circuit board 22 furthermore has indication elements 30. The latter are light-emitting diodes in the case of the example. Furthermore, at least one physical interface (transceiver) and terminating resistors for a CAN bus system are provided on the exchangeable circuit board 22. Moreover, plug connection elements 26 of RS232 interfaces are situated on the exchangeable circuit board 22.

The exchangeable circuit board 22 is releasably fixed to a cover screen 32, which is illustrated in cut-away fashion in FIG. 1 and closes an access opening 34 in the side part 10 of the housing 12. The cover screen 32 is screwed to the side part 10. A screw joint is discernible at 36.

As can be seen from FIG. 1, the exchangeable circuit board 22 is large enough that it can be removed from the housing 12 through the access opening 34 after the relevant screws 36 have been released. In this case, the plug connection 20 is automatically separated. In a correspondingly simple manner, the exchangeable circuit board 22 can be introduced into the housing 12 again with the plug connection 20 being established and be installed in a functional manner in the process. The above explanations directly reveal that the demounting and the installation of exchangeable circuit boards 22 can be effected very rapidly in a simple manner, be it for the purpose of exchanging the exchangeable circuit board 22 or for the purpose of checking the components 24, 26, 28, 30.

Since the components with the greatest probability of failure are provided on the exchangeable circuit board 22, disturbances of the control stage can be eliminated with a relatively high degree of probability by exchanging the exchangeable circuit board 22. Since the exchangeable circuit board 22 is populated with comparatively few components, it may perfectly well be expedient to find defective components of the exchangeable circuit board 22 by defect analysis and to exchange or repair them in order then to start using the exchangeable circuit board 22 again.

In FIG. 1, 40 denotes a fan device that is provided for cooling the circuit arrangement, in particular the power output stage 14.

FIG. 2 illustrates a block diagram of the circuit arrangement provided in the control unit according to FIG. 1. It shows that the exchangeable circuit board 22 is connected to external signal transmission lines or data transmission lines 42 by means of its interface terminals 26, 28, which lines, at the other end, are connected to external transmitters, motor sensors, vehicle sensors and, possibly, a central controller of the forklift truck.

The exchangeable circuit board 22 is connected to the main circuit board 16 via the plug connection 20. The main circuit board 16 is electrically connected to the power output stage circuit board 14 via the terminals 44 in order to control the power transistors for the traction driving motor, the pump driving motor and the steering motor. The power output stage circuit board 14 is connected via lines 46 to the onboard battery of the electric forklift truck and outputs electrical energy to the electric motor or the electric motors in a controlled manner via the line terminals 4, 6, 8.

1. A circuit arrangement for controlling electromotive driving means of a mobile working machine, particularly of an industrial truck, the circuit arrangement comprising an electronic control stage and a power output stage, the electronic control stage having at least one main circuit board that is fixed in a housing of the circuit arrangement and is populated with electronic components and an exchangeable circuit board that is electrically connected to the main circuit board but can be separated from the main circuit board as required with little effort, the exchangeable circuit board having a group of selected control stage components for which, on account of their greater probability of failure, statistically, a greater need for exchanging and/or a greater need for checking exists than for the components of the main circuit board.

2. The circuit arrangement as claimed in claim 1, wherein the exchangeable circuit board is electrically connected to the main circuit board by at least one plug connection.

3. The circuit arrangement as claimed in claim 1, wherein the exchangeable circuit board has plug connection elements for connecting external signal lines, in particular data transmission lines.

4. The circuit arrangement as claimed in claim 1, wherein the exchangeable circuit board has optical indication elements.

5. The circuit arrangement as claimed in claim 1, wherein a maximum of 25%, in particular a maximum of 15%, of the number of electronic components of the control stage are provided on the exchangeable circuit board.

6. The circuit arrangement as claimed in claim 1, wherein the board size of the exchangeable circuit board corresponds at most to one third, in particular at most one quarter, of the board size of the main circuit board.

7. The circuit arrangement as claimed in claim 1, wherein through an access opening provided in a side part of the housing, the exchangeable circuit board is adapted to be separated from the main circuit board and to be removed from the housing or to be introduced into the housing and to be electrically connected to the main circuit board, and the exchangeable circuit board is arranged on a cover screen for closing the access opening.

8. The circuit arrangement as claimed in claim 1, wherein the power output stage has a circuit board that is populated with output stage components, is electrically connected to the main circuit board of the control stage and is accommodated together with the main circuit board and the exchangeable circuit board of the control stage in the housing.

9. A mobile working machine, in particular an industrial truck, having at least one electric traction motor and/or an electric motor for operating a lifting device and/or an electric steering motor, and having a circuit arrangement as claimed in claim 1, for controlling the at least one electric motor.
